(19) United States
(12) Patent Application Publication
(10) Pub. No.: US 2025/0246477 A1
(43) Pub. Date: Jul. 31, 2025

(54) ELECTRONIC PACKAGE AND A METHOD FOR FORMING THE SAME

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR)

(21) Appl. No.: 19/034,573

(22) Filed: Jan. 23, 2025

(30) Foreign Application Priority Data
Jan. 25, 2024 (CN) 202410108617.9

(51) Int. Cl. H01L 21/687; H01L 21/56; H01L 23/00; H01L 23/31; H01L 25/065

(52) U.S. Cl. CPC H01L 21/68757; H01L 21/565; H01L 21/68778; H01L 23/3121; H01L 24/16; H01L 25/0655; H01L 2224/16225; H01L 2924/1815

(57) ABSTRACT

An electronic package and a method for forming the same are provided. The method comprises: providing a substrate having a front surface and a back surface, wherein at least one electronic component is attached onto the front surface of the substrate, and the substrate comprises at least a non-polar material; forming a mold cap on the front surface of the substrate to encapsulate the at least one electronic component; loading the substrate onto a susceptor, wherein the susceptor comprises at least a polar material; and applying microwave radiation to the mold cap and the susceptor to cure the mold cap at least partially through the susceptor.

### TECHNICAL FIELD

The present application generally relates to semiconductor technology, and more particularly, to an electronic package and a method for forming the same.

### BACKGROUND OF THE INVENTION

The semiconductor industry is constantly faced with complex integration challenges as consumers want their electronics to be smaller, faster and higher performance with more and more functionalities packed into a single device. Typically, a semiconductor package may include key functional modules, such as semiconductor chips and interconnection structures, and a mold cap which encapsulates the modules. During a molding process, a molding material is first liquefied and forced into a molding chase. Then a heating process is applied to cure the molding material, which encapsulates the modules. However, it is noted that the conventional heating process of the curing step is high in energy consumption and low in efficiency, which results in a higher cost in fabrication.

Therefore, a need exists for a method for forming an electronic package with an improved energy efficiency.

### SUMMARY OF THE INVENTION

An objective of the present application is to provide a method for forming an electronic package with an improved energy efficiency.

According to an aspect of the present application, an electronic package and a method for forming the same is provided. The method comprises: providing a substrate having a front surface and a back surface, wherein at least one electronic component is attached onto the front surface of the substrate, wherein the substrate comprises at least a non-polar material; forming a mold cap on the front surface of the substrate to encapsulate the at least one electronic component; loading the substrate onto a susceptor, wherein the susceptor comprises at least a polar material; and applying microwave radiation to the mold cap and the susceptor to cure the mold cap at least partially through the susceptor.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1D illustrate various steps of a method for forming an electronic package according to a first embodiment of the present application.

FIG. 2 illustrates a step of a method for forming an electronic package according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, a semiconductor package may include key functional modules, such as semiconductor chips and interconnection structures, and a mold cap which encapsulates the modules. During a molding process, a molding material is first liquefied and forced into a molding chase. Then a heating process is applied to cure the molding material, which encapsulates the modules. However, it is noted that the conventional heating process of the curing step in current technology is high in energy consumption and low in efficiency, which results in a higher cost in fabrication. To address this issue, a new method for forming an electronic package is provided, which conducts curing of a molding material by incorporating microwave heating and convection heat transfer via a susceptor. The method can be used in forming an electronic package such as a system-in-package (SIP) device or a package-in-package (PIP) device.

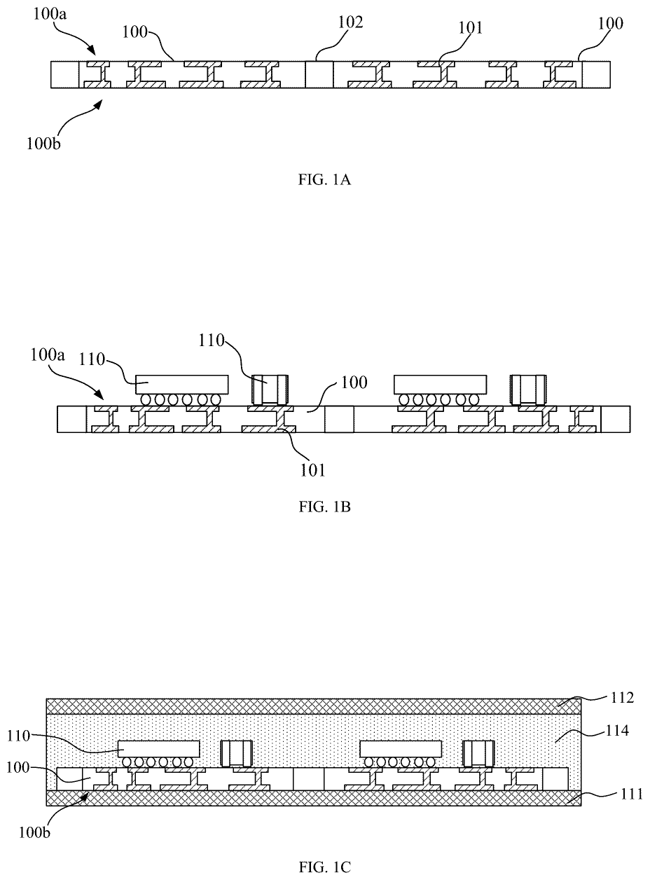

FIGS. 1A to 1D illustrate various steps of a method for forming an electronic package according to a first embodiment of the present application. In the following, the method will be described with reference to FIGS. 1A to 1D in more details.

As shown in FIG. 1A, a plurality of substrates or substrate units 100 may be provided in a substrate strip such that each of the substrates 100 may serve as a platform where an electronic package can be formed on. In this embodiment, the substrate strip may also include a plurality of linkage portions 102, each of which is positioned between two adjacent substrates 100, thus connecting the plurality of substrates 100 as the substrate strip. In this embodiment, each of the substrates 100 may have the same or similar structure. For simplicity, the following steps of forming the electronic package may be illustrated with reference to one of the substrates 100. As can be appreciated that a plurality of electronic packages may be formed using the same processing on the plurality of substrates 100. Also, it can be appreciated that in some embodiments both the linkage portions 102 and the substrates 100 are originally formed within the substrate strip and are not required to be assembled together as the substrate strip.

Still referring to FIG. 1A, the substrate 100 is provided with embedded interconnect wires 101. The substrate 100 may include a front surface 100a and a back surface 100b, which are opposite to each other. The front surface 100a of the package substrate 100 may serve as a platform where electronic component(s) can be mounted. Multiple sets of conductive pads (not shown) can be formed on the front surface 100a of the substrate 100 for the mounting of the electronic components. It can be appreciated that the multiple sets of conductive pads may be exposed portions of interconnect wires 101 formed within the substrate 100.

The substrate 100 includes at least a non-polar material, such as silicon, which is the main part of the materials of the substrate 100. It should be noted that the substrate 100 may also contain a minor amount of polar materials. For example, in this embodiment, the substrate 100 may contain more than 99 wt. % of non-polar material(s) and less than 1 wt. % of polar material(s), which may be helpful to improve structural and electrical performances of the substrate 100. In some other embodiments, it can be appreciated that the substrate 100 may contain less than 2 wt. %, 5 wt. % or 10 wt. %. of polar materials.

As shown in FIG. 1B, a solder material is deposited onto the front surface of the substrate 100 to form a plurality of solder bumps on the multiple sets of conductive pads. The solder material can be Al, Sn, Ni, Au, Ag, lead (Pb), bismuth (Bi), Cu, or combinations thereof.

Next, at least one electronic component 110 is attached onto the front surface 100a of the substrate 100 via the solder bumps, thus forming electrical connection between the interconnect wires 101 and the electronic component 110. In some embodiments, the electronic component 110 may be semiconductor chips or smaller semiconductor packages. It can be appreciated that more electronic components 110 may be mounted onto the front surface 110a according to actual needs of the electronic package to be formed.

Next, a mold cap 114 is formed on the front surface 100a of the substrate 100 to encapsulate the at least one electronic component 110. As shown in FIG. 1C, the substrate strip with a plurality of substrates 100 is loaded between a bottom chase 111 and a top chase 112 with the back surfaces 110b of the substrates 100 in contact with the bottom chase 111. Next, a molding material may be provided and first liquefied by heat and pressure, and then forced into a molding cavity which is defined by the bottom chase 111 and the top chase 112, thus covering surfaces of the electronic component(s) 110 on each of the substrates 100 and forming the mold cap 114. The molding material includes thermosetting materials such as epoxy, polyester resin, etc. In some embodiments, the mold cap 114 may be formed using various other molding technologies, including a transfer molding process, a compression molding process or a film-assisted molding (FAM) process.

Next, as shown in FIG. 1D, the substrate strip and the electronic components 110 thereon may be removed from the top chase 112 and the bottom chase 111. Then the substrate strip may be transferred to a chamber for subsequent microwave curing process. In this embodiment, before the microwave curing process, the substrate strip is loaded onto a susceptor 120 with the back surface 100b of the substrates 100 in contact with the susceptor 120. The susceptor 120 may include a polar material, a combination of polar materials, or a combination of polar and non-polar materials, which can be heated in a subsequent curing step of the mold cap 114 by microwave radiation. In addition, the susceptor 120 may include thermal conductive material(s), which allows for sufficient convection heat transfer from the susceptor 120 to the substrates 100 and the mold cap 114 as well as alleviation of heat dissipation of the mold cap 114 in the curing process of the mold cap 114 after it is heated by microwave radiation. In some embodiments, a significant portion (e.g., greater than 50 wt. %, 60 wt. %, 70 wt. %, 80 wt. %, 90 wt. %, 95 wt. % or 99 wt. %) of the susceptor 120 is formed of polar material(s), which offers a better heating performance when exposed to microwave radiation. To be more specific, the susceptor 120 may include at least one polar material selected from a group of silicon carbide, graphite, charcoal with polarity and carbon with polarity. In some other embodiments, the susceptor 120 may include a non-polar base coated with polar material(s) or distributed with polar materials(s), which may lower the requirement on materials of the susceptor 120 and achieve a better mechanical support and a reduced cost during the curing step of the mold cap 114, if appropriate materials for the non-polar base are used. Particularly, the non-polar base may include a silicon wafer or silicon powders, and the polar coating may include at least one polar material selected from a group of silicon carbide, graphite, charcoal with polarity or carbon with polarity.

Next, still referring to FIG. 1D, microwave radiation is applied to the mold cap 114 and the susceptor 120 to cure the mold cap 114. In some embodiments, a microwave source is placed above a top surface of the mold cap 114, and then microwave radiation is applied from the microwave source to the mold cap 114. The mold cap 114 can be heated by the microwave radiation due to the polar materials contained therein, thereby enabling the curing of the mold cap 114 to encapsulate the electronic components 110 on the substrates 100.

At the same time, the susceptor 120 is also exposed to the microwave radiation, where the microwave radiation may penetrate the mold cap 114 and the substrates 100, and finally reach the susceptor 120. In addition, the microwave radiation may also directly reach the susceptor 120 from lateral surfaces and a bottom surface of the susceptor 120 which are not blocked by the substrates 100. Since the susceptor 120 is at least partially formed of a polar material, dipoles within polar molecules of the susceptor 120 are sensitive to an electrical field of the microwave and may rotate to align themselves with a direction of the electrical field. The electrical field of the microwave is periodically changing, which may prompt the dipoles to rotate frequently. As a result, the dipoles may collide with each other when they attempt to follow the electrical field, which generates heat energy in the susceptor 120. Then the heat generated in the susceptor 120 may be convectively transferred to the substrates 100 and the mold cap 114, which provides additional heat energy to the mold cap 114 during the curing process. In this way, the mold cap 114 may be cured through a hybrid heating mechanism which incorporates the direct microwave curing of the mold cap 114 and the convection heat transferred from the susceptor 120. With additional heat energy introduced to the mold cap 114 during the curing process, the curing of the mold cap 114 may have a higher energy efficiency, thus leading to a lower energy demand from the microwave source. Moreover, with a lower microwave energy applied from the microwave source, overall heat generated within the device may be reduced, which may prevent or alleviate a burning effect caused by excessive microwave energy. In addition, since a bottom part of the mold cap with less exposure to the microwave radiation may receive more heat energy which is convectively transferred from the susceptor 120, the mold cap 114 may be cured in a more uniform and controlled way with fewer defects. In short, an excess amount of microwave energy which cannot be absorbed by the mold cap 114 may be collected by the susceptor 120 and converted into heat, which, in turn, helps for the curing of the mold cap 114. In some embodiments, the susceptor 120 may include at its bottom side a film or a plate which can reflect microwave upward. During the curing process, the reflected microwave may again penetrate the susceptor 120 and generate heat there, or even penetrate the susceptor 120 and reach the mold cap 114 to cure the mold cap 114.

Furthermore, in this embodiment, the microwave radiation is applied at variable frequencies during the microwave radiation step. By sweeping a range of frequencies rapidly, the microwave radiation process may increase the uniformity of microwave energy in comparison with a fixed-frequency microwave. In some embodiments, the microwave radiation is applied at a frequency ranging between 1 GHz and 10 GHz. During the step of applying microwave radiation to the mold cap 114 and the susceptor 120, the mold cap 114 is heated by microwave radiation and sufficient convection heat transfer may occur from the susceptor 120 to the substrates 100 and the mold cap 114. Furthermore, the heated susceptor 120 may help to alleviate heat dissipation of the mold cap 114 and help to keep the mold cap 114 at a relatively high temperature, which may contribute to a sufficient heating process of the mold cap 114.

In some embodiments, the heated mold cap 114 may reach a temperature ranging between 60° C. and 180° C. when heated by the microwave radiation for curing. At the same time, the susceptor 120 which is heated by the microwave radiation may reach a temperature ranging between 50° C. and 100° C., which alleviates warpage of the device in a most controlled way along with a sufficient curing process of the mold cap 114. In some other embodiments, it can also be appreciated that the microwave radiation is applied at a frequency lower than 1 GHZ, which may further reduce the warpage of the device, or at a frequency higher than 10 GHZ, which may lead to a more rapid curing process of the mold cap 114. The selection of the frequency of the microwave radiation may also depend on the materials of the mold cap 114 and the susceptor 120.

After the curing process of the mold cap 114, each of the substrates 100 may be singulated from the substrate strip with the electronic components 110 and the mold cap 114 thereon. The singulation may be conducted along the linkage portions 102. The singulation process may include removing the mold cap 114 above the linkage portions 102 first and then removing the linkage portions 102 to separate the substrates 100 from each other. After the singulation, each substrate 100 with the electronic components 110 and the mold cap 114 thereon forms an electronic package. In some other embodiments, the singulation of the substrates 100 may be conducted before the step of applying the microwave radiation to the mold cap 114 and the susceptor 120 which is illustrated in FIG. 1D, or even before the molding step which is illustrated in FIG. 1C.

As mentioned above, in the embodiment shown in FIG. 1D, a microwave source is placed above a top surface of the mold cap 114. In some other embodiments, a flipping mechanism may be arranged in the chamber, which is configured for flipping the substrate 100 and the components thereon. The curing of the mold cap 114 may be divided into two successive heating steps. In the first heating step, the mold cap 114 and the susceptor 120 may be heated by a microwave source which is placed above the mold cap 114. Thus, a closer distance to the microwave source may induce more effective heating of a top portion of the mold cap 114 compared with a bottom portion of the mold cap 114 which is in contact with the substrate 100. Then the substrate 100 and the components thereon may be flipped over by the flipping mechanism to conduct the second heating step. In the second heating step, the susceptor 120 and the bottom portion of the mold cap 114 which is in contact with the substrate 100 may be heated more effectively than the top portion of the mold cap 114. In this way, the overall curing process of the mold cap 114 may be more uniform and effective.

In some other embodiments, the microwave source may be placed at lateral sides of the mold cap 114 and the susceptor 120, which may be closer to the susceptor 120. The microwave radiation may be applied to the mold cap 114 and the susceptor 120 from their lateral sides. Therefore, the mold cap 114 is cured directly by the microwave radiation, and at the same time, the susceptor 120 may be heated by the microwave radiation more efficiently, allowing for a more sufficient convection heat transfer to the mold cap 114 and alleviation of heat dissipation of the mold cap 114.

In some alternative embodiments, the substrates 100 with the susceptor 120 and the mold cap 114 thereon may be fixed in middle of the chamber. Apart from the microwave source placed above a top surface of the mold cap 114, additional microwave sources may be placed below the susceptor 120, and thus the susceptor 120 may receive direct microwave radiation from the additional microwave sources, which enables more efficient heating to the susceptor 120. Therefore, energy applied from each of the microwave sources may be adjusted according to actual layouts of the electronic package devices, which leads to a more efficient and uniform heating process of the mold cap 114.

In the embodiment shown in FIGS. 1A to 1D, the substrate strip is loaded onto the susceptor 120 with the back surfaces 100b of the substrates 100 in contact with the susceptor 120. In an alternative embodiment, the substrate strip is loaded onto a susceptor with a top surface of the mold cap in contact with the susceptor, which will be elaborated below.

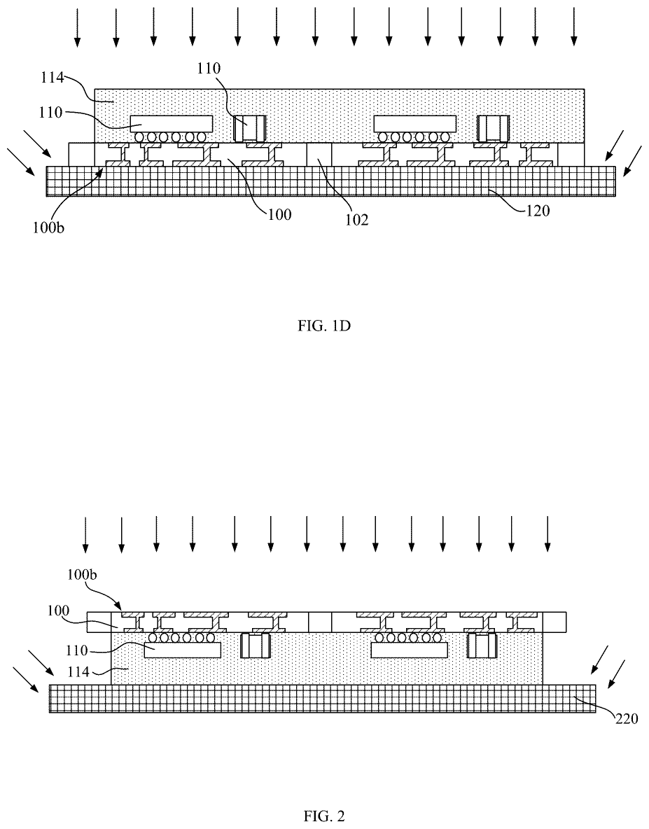

FIG. 2 illustrate a step of a method for forming an electronic package according to a second embodiment of the present application. The step illustrated in FIG. 2 may be implemented after the steps illustrated in FIGS. 1A to 1C have been performed, instead of the step illustrated in FIG. 1D, as an alternative embodiment to the embodiment shown in FIGS. 1A to 1D.

In particular, the substrate strip and the electronic components 110 thereon may be removed from the top chase 112 and the bottom chase 111 which are used in the step illustrated in FIG. 1C. Then the substrate strip may be transferred to a chamber for subsequent microwave curing process. In this embodiment, before the microwave curing process, the substrate strip is first flipped over and loaded onto a susceptor 220 with a top surface of the mold cap 114 in contact with the susceptor 220, where the top surface of the mold cap 114 is the surface away from the substrates 100. The material and functionality of the susceptor 220 is similar with that of the susceptor 120 illustrated in FIG. 1D, which will not be elaborated below.

Next, microwave radiation is applied to the mold cap 114 and the susceptor 220 to cure the mold cap 114. In the embodiment shown in FIG. 2, a microwave source is placed above the substrate 100, and then microwave radiation is applied from the microwave source to the mold cap 114 and the susceptor 220. The mold cap 114 material is heated by the microwave radiation, enabling the curing of the mold cap 114 to encapsulate the electronic components 110 on the substrates 100. At the same time, the susceptor 220 may also be heated by the microwave radiation. Since the susceptor 220 is directly in contact with the top surface of the mold cap 114, the convection heat transfer from the susceptor 220 to the mold cap 114 and alleviation of heat dissipation of the mold cap 114 may be more efficient, which provides extra heat energy to the mold cap 114 during the curing process, leading to a higher energy efficiency of the curing process. In some other embodiments, the microwave source may be placed at a bottom portion of the chamber, e.g., below the susceptor 220, and thus the susceptor 220 may receive direct microwave radiation from the microwave source, which enables more efficient heating to the susceptor 220 and then allows for more effective convection heat transfer to the mold cap 114 and alleviation of heat dissipation of the mold cap 114. In an alternative embodiment, the substrate 100 and structures thereon may be flipped over to be heated by microwave radiation from a microwave source which is placed at a top portion of the chamber.

In some other embodiments, apart from the susceptor 220 on the top surface of the mold cap 114, the substrate 100 may also be loaded onto an additional susceptor (not shown) with back surfaces 100b of the substrates 100 in contact with the additional susceptor, which provides convection heat transfer to the mold cap 114 and alleviation of heat dissipation of the mold cap 114 from the top surface and a bottom surface of the mold cap 114, resulting in a more uniform and efficient curing process. In addition, at least one microwave source may be placed at least at one of the following positions: above the additional susceptor, below the susceptor 220 or at lateral sides of the substrate 100 according to actual layouts of the device.

In some embodiments, an electronic package formed by implementing any of the above methods can be applied in any semiconductor package devices such as a system-in-package (SIP) device or a package-in-package (PIP) device.

While the exemplary method for forming an electronic package of the present application is described in conjunction with corresponding figures, it will be understood by those skilled in the art that modifications and adaptations to an electronic package may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic package, the method comprising:
providing a substrate having a front surface and a back surface, wherein at least one electronic component is attached onto the front surface of the substrate, and the substrate comprises at least a non-polar material;
forming a mold cap on the front surface of the substrate to encapsulate the at least one electronic component;
loading the substrate onto a susceptor, wherein the susceptor comprises at least a polar material; and
applying microwave radiation to the mold cap and the susceptor to cure the mold cap at least partially through the susceptor.

2. The method of claim 1, wherein the susceptor comprises a thermal conductive material or thermal conductive materials.

3. The method of claim 2, wherein the susceptor comprises at least one polar material selected from a group of silicon carbide, graphite, charcoal with polarity and carbon with polarity.

4. The method of claim 2, wherein the susceptor comprises a non-polar base coated with a polar coating.

5. The method of claim 4, wherein the non-polar base comprises a silicon wafer or silicon powders, and the polar coating comprises at least one polar material selected from a group of silicon carbide, graphite, charcoal with polarity or carbon with polarity.

6. The method of claim 1, wherein loading the substrate onto a susceptor comprises:
loading the substrate onto the susceptor with the back surface of the substrate in contact with the susceptor.

7. The method of claim 1, wherein loading the substrate onto a susceptor comprises:
loading the substrate onto the susceptor with a top surface of the mold cap in contact with the susceptor.

8. The method of claim 7, wherein after loading the substrate onto the susceptor with a top surface of the mold cap in contact with the susceptor, the method further comprises:
loading the substrate onto an additional susceptor with the back surface of the substrate in contact with the additional susceptor.

9. The method of claim 1, wherein the microwave radiation is applied at a frequency ranging between 1 GHz and 10 GHz.

10. The method of claim 1, wherein during the step of applying microwave radiation to the mold cap and the susceptor, a temperature of the susceptor ranges between 50° C. and 100° C.

11. The method of claim 1, wherein the microwave radiation is applied at variable frequencies during the step of applying microwave radiation.

12. An electronic package which is formed using the method of claim 1.
